(19) United States
(12) Patent Application Publication
(10) Pub. No.: US 2017/0250667 A1
(43) Pub. Date: Aug. 31, 2017

(54) SUB-BAND ADJUSTABLE BANDPASS FILTER

(71) Applicant: Samsung Electro-Mechanics Co., Ltd., Suwon-si (KR)

(72) Inventor: Seong Jong CHEON, Suwon-si (KR)

(73) Assignee: Samsung Electro-Mechanics Co., Ltd., Suwon-si (KR)

(21) Appl. No.: 15/266,302

(22) Filed: Sep. 15, 2016

(30) Foreign Application Priority Data
Feb. 29, 2016 (KR) 10-2016-0023945

(51) Int. Cl. H03H 7/01; H03H 7/09

(52) U.S. Cl. CPC H03H 7/0161; H03H 7/0115; H03H 7/09

(57) ABSTRACT

A bandpass filter includes resonance circuits and an inductance circuit. The resonance circuits are coupled to variable capacitance circuits, respectively. The inductance circuit is coupled to the variable capacitance variable circuits. The resonance circuits are individually controllable by respectively connected variable capacitance circuit to resonate at different frequencies.

### CROSS-REFERENCE TO RELATED APPLICATION(S)

This application claims the benefit under 35 U.S.C. 119(a)of Korean Patent Application No. 10-2016-0023945 filed on Feb. 29, 2016, in the Korean Intellectual Property Office, the entire disclosure of which is incorporated herein by reference for all purposes.

### BACKGROUND

1. Field

The following description relates to a sub-band adjustable bandpass filter to be applied to an Ultra-Wideband (UWB) system.

2. Description of Related Art

Ultra-Wideband (UWB) technology is used to transmit at a frequency band of 3.1 GHz to 10.6 GHz between a transmission distance of 0.01 km-1 km. The frequency band is suitable for transferring high capacity information at low power over a broad signal bandwidth. However, the standards of bands and bandwidths in various countries are not uniformly defined.

A method of operating a variable bandpass filter widely used in multi-mode multi-band communications can largely be classified as one of three methods, namely: a method of adjusting a width of a frequency band, a method of moving a frequency band by varying the center frequency, and a method of selectively using a filter having various bands as a frequency band using a switch.

Meanwhile, with regard to UWB, the 3.1 GHz to 10.6 GHz band is available in the United States, but only the 3.4 GHz to 4.8 GHz and 7.25 GHz to 10.25 GHz bands are available for use in Japan. For signals of the 5GHz, the IEEE 802.11a standard is used. The frequency band, which is an ISM band, can be used while being divided into two frequency bands.

However, the typical UWB system includes a filter designed and manufactured specifically for each country to account for variations in band and frequency availability. For example, a UWB bandpass filter for a single broad band in the United States and a UWB bandpass filter for a two-frequency band in Japan are different.

Thus, as different types of filters may need to be developed for use in different countries, development costs and production costs thereof is increased. In addition, a single filter cannot be applied to a UWB system used in different regions.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a sub-band adjustable bandpass filter includes a first resonance circuit, a second resonance circuit, a first variable capacitance circuit, a second variable capacitance circuit, and an inductance circuit. The first resonance circuit is configured to resonate at a first frequency. The second resonance circuit is configured to resonate at a second frequency different from the first frequency. The first variable capacitance circuit is connected between a first node connected to the first resonance circuit and a common node, and has capacitance value varied responsive to a first control signal. The second variable capacitance circuit is connected between a second node connected to the second resonance circuit and the common node, and has capacitance value varied responsive to a second control signal. The inductance circuit and the first variable capacitance circuit define a first parallel resonance circuit. The inductance circuit and the second variable capacitance circuit defines a second parallel resonance circuit. The inductance circuit and the first variable capacitance circuit defines a first series resonance circuit. The inductance circuit and the second variable capacitance circuit defines a second series resonance circuit.

Resonance frequencies of the first parallel resonance circuit and the second parallel resonance circuit, and resonance frequencies of the first series resonance circuit and the second series resonance circuit may be varied responsive to the first control signal and the second control signal, respectively.

The first resonance circuit may include a first inductor and a first capacitor serially connected between a first terminal and the first node, and the first inductor and the first capacitor may resonate in series at the first frequency.

The second resonance circuit may include a second inductor and a second capacitor serially connected between a second terminal and the second node, and the second inductor and the second capacitor may resonate in series at the second frequency.

The first variable capacitance circuit may include at least a first variable capacitor circuit connected between the first node and the common node, and capacitance value of the first variable capacitor circuit may be varied responsive to the first control signal.

The second variable capacitance circuit may include at least a second variable capacitor circuit connected between the second node and the common node, and capacitance value of the second variable capacitor circuit may be varied responsive to the second control signal.

The inductance circuit may include a first inductor, a second inductor, and a common inductor. The first inductor, the first inductor and the first variable capacitance circuit define the first parallel resonance circuit to resonate in parallel at a third frequency. The second inductor and the second variable capacitance circuit define the second parallel resonance circuit to resonate in parallel at a fourth frequency. The common inductor may be connected between the common node and a ground. The common inductor and the first variable capacitance circuit define the first series resonance circuit. The common inductor and the second variable capacitance circuit define the second series resonance circuit, to resonate in series at a fifth frequency.

In another general aspect, a sub-band adjustable bandpass filter includes a first resonance circuit, a second resonance circuit, a first variable capacitance circuit, a second variable capacitance circuit, and an inductance circuit. The first resonance circuit is configured to resonate at a first frequency. The second resonance circuit is configured to resonate at a second frequency different from the first frequency. The first variable capacitance circuit is connected between a first node connected to the first resonance circuit and a common node, and has capacitance value being varied responsive to a first control signal. The second variable capacitance circuit is connected between a second node connected to the second resonance circuit and the common node, and has capacitance value being varied responsive to a second control signal. The inductance circuit includes a first inductor, a second inductor, and a common inductor connected between the common node and a ground. The first inductor and the first variable capacitance circuit define a first parallel resonance circuit. The second inductor and the second variable capacitance circuit define a second parallel resonance circuit. The common inductor and the first variable capacitance circuit define a first series resonance circuit. The common inductor and the second variable capacitance circuit define a second series resonance circuit, wherein the first inductor and the second inductor form inductive coupling.

The first resonance circuit may include the first inductor and a first capacitor serially connected between a first terminal and the first node in series. The first inductor and the first capacitor may resonate in series at the first frequency.

The second resonance circuit may include the second inductor and a second capacitor serially connected between a second terminal and the second node in series. The second inductor and the second capacitor may resonate in series at the second frequency.

The first variable capacitance circuit may include at least a first variable capacitor circuit connected between the first node and the common node, and capacitance value of the first variable capacitor circuit may be varied responsive to the first control signal.

The second variable capacitance circuit may include at least a second variable capacitor circuit connected between the second node and the common node, and capacitance value of the second variable capacitor circuit may be varied responsive to the second control signal.

The first inductor of the inductance circuit and the first variable capacitance circuit may configure the first parallel resonance circuit to resonate in parallel at a third frequency. The second inductor of the inductance circuit and the second variable capacitance circuit may configure the second parallel resonance circuit to resonate in parallel at a fourth frequency. The common inductor of the inductance circuit and the first variable capacitance circuit may configure the first series resonance circuit and the common inductor thereof. The second variable capacitance circuit may configure the second series resonance circuit, to resonate in series at a fifth frequency.

In another general aspect, a bandpass filter includes resonance circuits and an inductance circuit. The resonance circuits are coupled to variable capacitance circuits, respectively. The inductance circuit is coupled to the variable capacitance variable circuits. The resonance circuits are individually controllable by respectively connected variable capacitance circuit to resonate at different frequencies.

An Ultra-wideband filter may include the bandpass filter.

A first resonance circuit of the resonance circuits may resonate at a first frequency between 2 GHz to 8 GHz.

A second resonance circuit of the resonance circuits may resonate at a second frequency between 2 GHz to 8 GHz.

The first frequency may be different from the second frequency.

Each of the variable capacitance circuits may include a control signal that is used to control the frequency of a respective resonance circuit.

Other features and aspects will be apparent from the following detailed description, the drawings, and the claims.

### BRIEF DESCRIPTION OF DRAWINGS

FIG. 1 is a block diagram of a sub-band adjustable bandpass filter according to an embodiment.

FIG. 2 is t of a circuit diagram of a sub-band adjustable bandpass filter according to an embodiment.

FIG. 3 is of a circuit diagram of a sub-band adjustable bandpass filter according to another embodiment.

FIGS. 4A and 4B are examples of first variable capacitance circuits.

FIGS. 5A and 5B are examples of second variable capacitance circuits.

FIGS. 6A and 6B are graphs illustrating frequency response characteristics according to various embodiments.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known in the art may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when an element, such as a layer, region, or substrate, is described as being “on,” “connected to,” or “coupled to” another element, it may be directly “on,” “connected to,” or “coupled to” the other element, or there may be one or more other elements intervening therebetween. In contrast, when an element is described as being “directly on,” “directly connected to,” or “directly coupled to” another element, there can be no other elements intervening therebetween.

As used herein, the term “and/or” includes any one and any combination of any two or more of the associated listed items.

Although terms such as “first,” “second,” and “third” may be used herein to describe various members, components, regions, layers, or sections, these members, components, regions, layers, or sections are not to be limited by these terms. Rather, these terms are only used to distinguish one member, component, region, layer, or section from another member, component, region, layer, or section. Thus, a first member, component, region, layer, or section referred to in examples described herein may also be referred to as a second member, component, region, layer, or section without departing from the teachings of the examples.

The terminology used herein is for describing various examples only, and is not to be used to limit the disclosure. The articles “a,” “an,” and “the” are intended to include the plural forms as well, unless the context clearly indicates otherwise. The terms “comprises,” “includes,” and “has” specify the presence of stated features, numbers, operations, members, elements, and/or combinations thereof, but do not preclude the presence or addition of one or more other features, numbers, operations, members, elements, and/or combinations thereof.

The features of the examples described herein may be combined in various ways as will be apparent after an understanding of the disclosure of this application. Further, although the examples described herein have a variety of configurations, other configurations are possible as will be apparent after an understanding of the disclosure of this application.

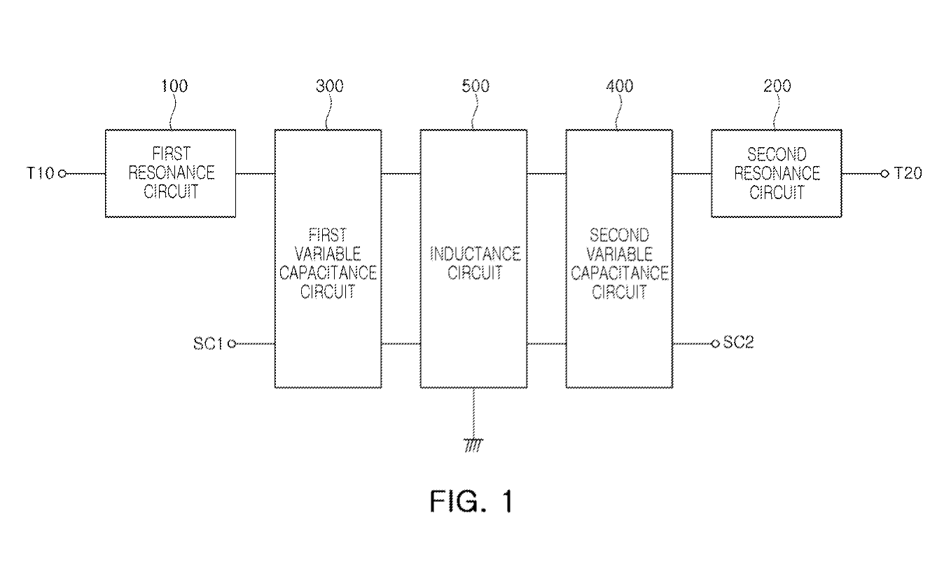

FIG. 1 is a diagram of a sub-band adjustable bandpass filter according to an embodiment.

With reference to FIG. 1, a sub-band adjustable bandpass filter includes a first resonance circuit 100, a second resonance circuit 200, a first variable capacitance circuit 300, a second variable capacitance circuit 400, and an inductance circuit 500.

The first resonance circuit 100 resonates at a first frequency f1. For example, the first frequency f1 may be a frequency included in a range of 2 GHz to 8 GHz, such as 4 GHz or 6 GHz.

The second resonance circuit 200 resonates at a second frequency f2 different from the first frequency f1. For example, the second frequency f2 may be a frequency included in a range of 2 GHz to 8 GHz, such as 4 GHz or 6 GHz.

The first variable capacitance circuit 300 is connected between the first resonance circuit 100 and the inductance circuit 500. The first variable capacitance circuit 300 is varied responsive to a first control signal SC1.

To this end, the first variable capacitance circuit 300 includes at least one variable capacitive element such as a varactor and/or a switched capacitor circuit having a switch and a capacitor.

The second variable capacitance circuit 400 is connected between the second resonance circuit 200 and the inductance circuit 500. The second variable capacitance circuit 400 is varied responsive to a second control signal SC2.

To this end, the second variable capacitance circuit 400 includes at least one variable capacitive element such as a varactor and/or a switched capacitor circuit having a switch and a capacitor.

In addition, the inductance circuit 500 and the first variable capacitance circuit 300 form a first parallel resonance circuit, and the inductance circuit 500 and the second variable capacitance circuit 400 form a second parallel resonance circuit.

In addition, the inductance circuit 500 and the first variable capacitance circuit 300 form a first series resonance circuit, and the inductance circuit 500 and the second variable capacitance circuit 400 form a second series resonance circuit.

Resonance frequency of the first parallel resonance circuit and resonance frequency of the first series resonance circuit is varied responsive to the first control signal SC1.

In addition, resonance frequency of the second parallel resonance circuit and resonance frequency of the second series resonance circuit may be varied according to the second control signal SC2.

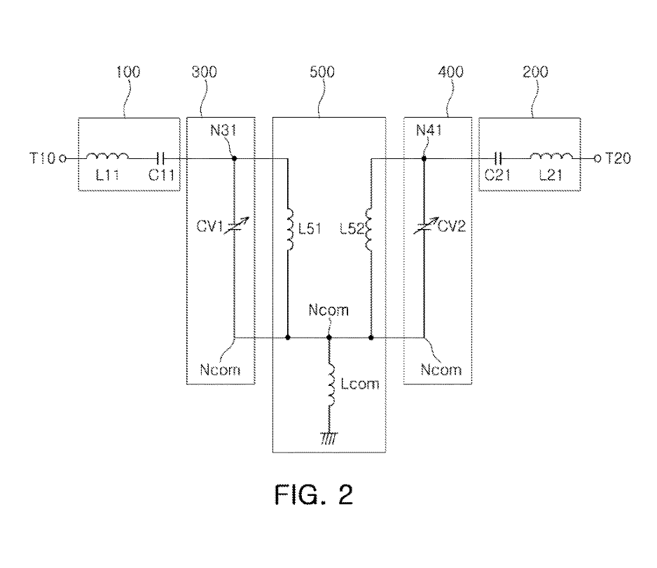

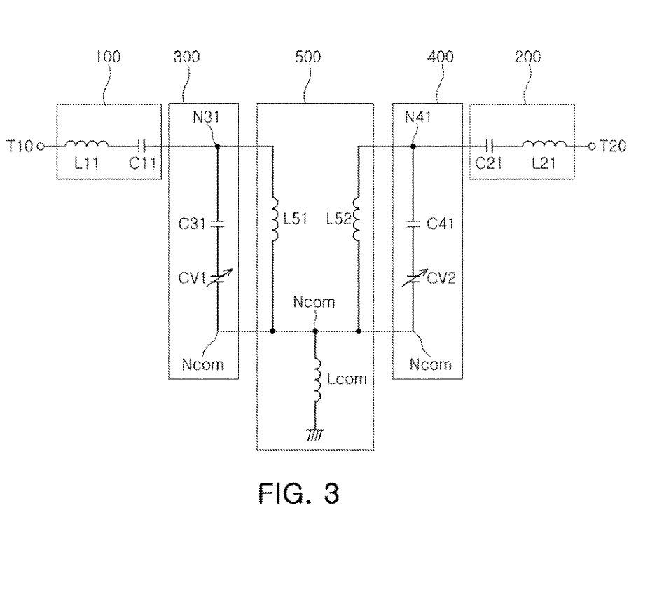

FIG. 2 is a first of a circuit of a sub-band adjustable bandpass filter according to an embodiment, and FIG. 3 is a second of a circuit of a sub-band adjustable bandpass filter according to another embodiment.

With reference to FIGS. 2 and 3, the first resonance circuit 100 includes a first inductor L11 and a first capacitor C11 serially connected between a first terminal T10 and the first node N31. The first inductor L11 and the first capacitor C11 resonate in series at the first frequency f1.

The second resonance circuit 200 includes a second inductor L21 and a second capacitor C21 serially connected between a second terminal T20 and the second node N41. The second inductor L21 and the second capacitor C21 may resonate in series at the second frequency f2.

For example, the first frequency f1 and the second frequency f2 may be a frequency included in a range of 2 GHz to 8 GHz. In detail, the first frequency f1 and the second frequency f2 may be the same, e.g., 5 GHz, or 4 GHz and 6 GHz, respectively.

The first variable capacitance circuit 300 includes at least a first variable capacitor circuit CV1 connected between the first node N31 and the common node Ncom.

With reference to FIG. 3, the first variable capacitance circuit 300 includes a first capacitor C31 and a first variable capacitor circuit CV1 serially connected between the first node N31 and the common node Ncom.

With reference to FIGS. 2 and 3, capacitance of the first variable capacitor circuit CV1 may be varied responsive to the first control signal SC1.

Here, the first variable capacitor circuit CV1 may include at least one variable capacitive element such as a varactor and/or a switched capacitor circuit having a switch and a capacitor.

The second variable capacitance circuit 400 includes at least a second variable capacitor circuit CV2 connected between the second node N41 and the common node Ncom.

With reference to FIG. 2, the second variable capacitance circuit 400 includes a second variable capacitor circuit CV2 connected between the second node N41 and the common node Ncom.

With reference to FIG. 3, the second variable capacitance circuit 400 may include a second capacitor C41 and the second variable capacitor circuit CV2 connected serially between the second node N41 and the common node Ncom.

Capacitance of the second variable capacitor circuit CV2 may be varied according to the second control signal SC2.

Here, the second variable capacitor circuit CV2 includes at least one variable capacitive element such as a varactor, or a switched capacitor circuit including a switch and a capacitor.

With reference to FIGS. 2 and 3, the inductance circuit 500 includes a first inductor L51, a second inductor L52, and a common inductor Lcom.

The first inductor L51 and the first variable capacitance circuit 300 form the first parallel resonance circuit to resonate in parallel at a third frequency f3.

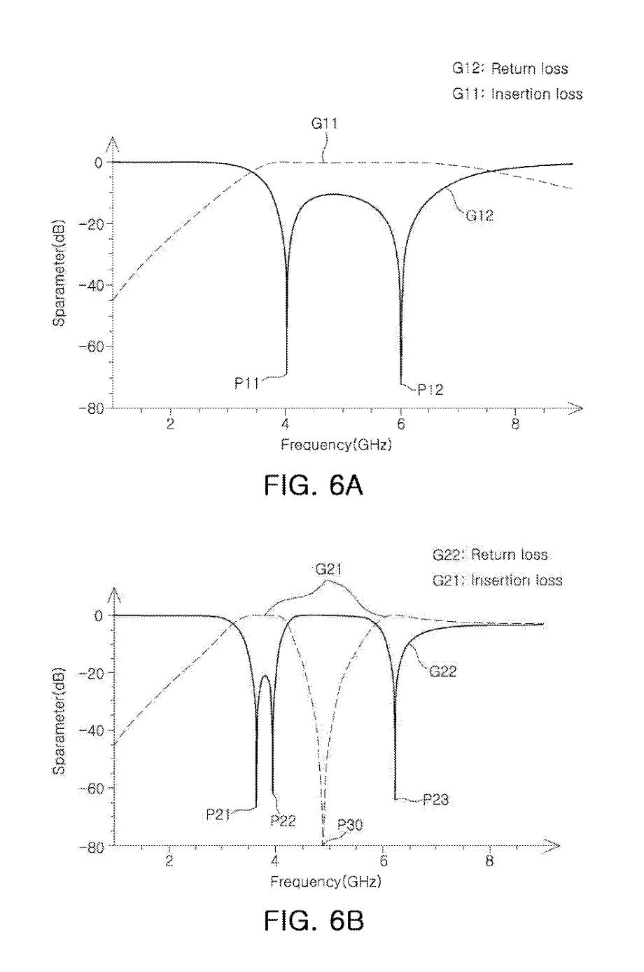

As an example, the third frequency f3 may be 4 GHz (P11 in FIG. 6A), or as another example, the third frequency f3 may be 3.75 GHz (P21 in FIG. 6B).

As described above, the third frequency f3 may be varied as capacitance of the first variable capacitance circuit 300 is varied.

The second inductor L52 and the second variable capacitance circuit 400 form the second parallel resonance circuit to resonate in parallel at a fourth frequency f4.

As an example, the fourth frequency f4 may be 6 GHz (P12 in FIG. 6A), or as another example, the fourth frequency f4 may be 4 GHz (P22 in FIG. 6B).

As described above, the fourth frequency f4 may be varied as capacitance of the second variable capacitance circuit 400 is varied.

The common inductor Lcom is connected between the common node Ncom and a ground, and thus, the common inductor Lcom and the first variable capacitance circuit 300 form the first series resonance circuit and the common inductor Lcom and the second variable capacitance circuit 400 form the second series resonance circuit, to resonate in series at a fifth frequency f5.

As an example, the fifth frequency f5 may be a frequency of 10 GHz or more (FIG. 6A), or as another example, the fifth frequency f5 may be about 4.8 GHz (P30 in FIG. 6B).

As described above, the fifth frequency f5 may be varied as capacitance of the first variable capacitance circuit 300 and capacitance of the second variable capacitance circuit 400 are varied.

Meanwhile, the first inductor L51 and the second inductor L52 form inductive coupling. Here, the inductive coupling means that when magnetic flux generated by one circuit, is interlinked with another circuit, the generated magnetic flux is inductively coupled to the circuit. By such inductive coupling, a phenomenon of energy transferal from one circuit to another circuit may occur.

As an example, when current flows on one side of the first inductor L51, a magnetic field is generated around the first inductor, and a portion of the magnetic field is coupled to the second inductor L52 on a different side. In this case, a mutual inductance value generated by inductive coupling between the first inductor L51 and the second inductor L52 may be determined by a distance between inductors, intensity of magnetic flux, or the like.

As described above, when the first inductor L51 and the second inductor L52 are coupled by mutual inductive coupling, a mutual inductance value of required inductive coupling allows a capacitance value of the common inductor Lcom to be determined through an equivalent circuit having an inductive coupling structure.

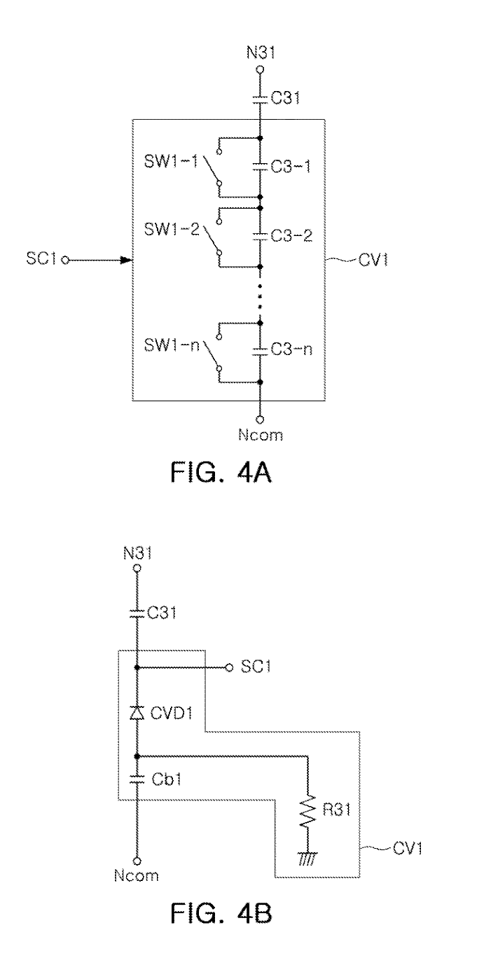

FIGS. 4A and 4B are examples of first variable capacitance circuits.

With reference to FIG. 4A, the first variable capacitor circuit CV1 of the first variable capacitance circuit 300 includes a plurality of capacitors C3-1 to C3-n serially connected to the first capacitor C31, and a plurality of switches SW1-1 to SW1-n connected in parallel to the plurality of capacitors C3-1 to C3-n, respectively. The first variable capacitor circuit CV1 is disposed between nodes N31 and N32, and controlled to be in an on state or in an off state by the first control signal SC1.

The first control signal SC1 includes a plurality of control signals to control the plurality of switches SW1-1 to SW1-n, respectively.

In this case, the first control signal SC1 controls each of the plurality of switches SW1-1 to SW1-n is to be in an on state or in an off state resulting in a variable capacitance value of the first variable capacitance circuit 300.

With reference to FIG. 4B, the first variable capacitor circuit CV1 of the first variable capacitance circuit 300 includes at least one first varactor diode CVD1 serially connected to the first capacitor C31, a resistance R31, and a direct current breaking capacitor Cb1.

When the first control signal SC1 is supplied to a cathode of the first varactor diode CVD1, a current path is formed by a ground connection through the first varactor diode CVD1 and the resistance R31, and the current path is interrupted by the direct current breaking capacitor Cb1.

In this case, capacitance of the first varactor diode CVD1 may be varied according to a voltage level of the first control signal SC1, and thus, capacitance of the first variable capacitance circuit 300 may be varied.

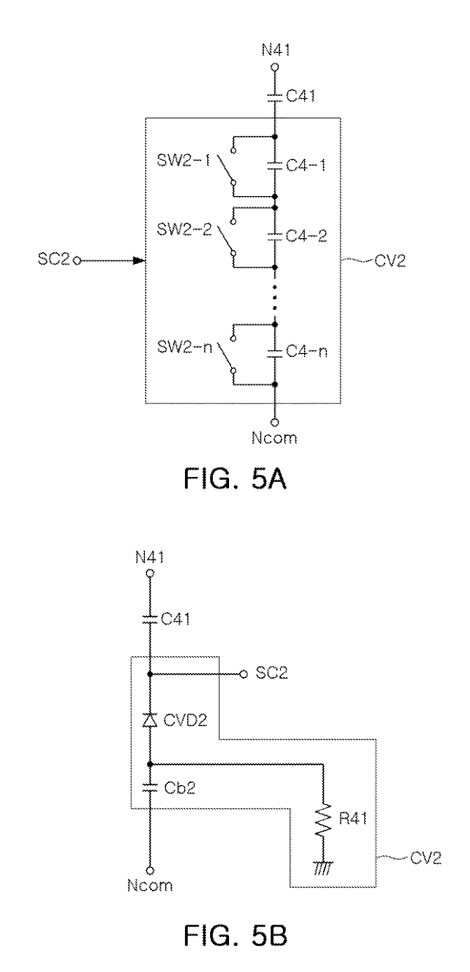

FIGS. 5A and 5B are examples of second variable capacitance circuits.

With reference to FIG. 5A, the second variable capacitor circuit CV2 of the second variable capacitance circuit 400 include a plurality of capacitors C4-1 to C4-nserially connected to the second capacitor C41, and a plurality of switches SW2-1 to SW2-n connected to the plurality of capacitors C4-1 to C4-n in parallel, respectively, and controlled to be in an on state or in an off state by the second control signal SC2.

The second control signal SC2 includes a plurality of control signals to control the plurality of switches SW2-1 to SW2-n, respectively.

In this case, each of the plurality of switches SW2-1 to SW2-n is to be in an on state or an off state by the second control signal SC2, and thus, capacitance of the second variable capacitance circuit 400 may be varied.

With reference to FIG. 5B, the second variable capacitor circuit CV2 of the second variable capacitance circuit 400 includes at least one second varactor diode CVD2 serially connected to the second capacitor C41, a resistance R41, and a direct current breaking capacitor Cb2.

When the second control signal SC2 is supplied to a cathode of the second varactor diode CVD2, a current path is formed by a ground connection through the second varactor diode CVD2 and the resistance R41, and current is interrupted by the direct current breaking capacitor Cb2.

In this case, capacitance of the second varactor diode CVD2 may be varied according to a voltage level of the second control signal SC2, and thus, capacitance of the second variable capacitance circuit 400 may be varied.

FIGS. 6A and 6B are graphs illustrating frequency response characteristics according to an embodiment.

A frequency response characteristic graph illustrated in FIG. 6A illustrates frequency response characteristics with respect to a bandpass filter for one broadband.

In FIG. 6A, G11 is an insertion loss graph, and G12 is a return loss graph. P11 and P12 are resonance points with respect to 4 GHz and 6 GHz in the return loss graph G12.

The frequency response characteristics illustrated in FIG. 6A may be changed to frequency response characteristics illustrated in FIG. 6B, as capacitance is varied to be increased and a resonance frequency is varied to be lowered by the first capacitance circuit 300 and the second capacitance circuit 400 as described before, in a bandpass filter according to an embodiment.

A frequency response characteristic graph illustrated in FIG. 6B illustrates frequency response characteristics with respect to a bandpass filter having two narrowbands.

In FIG. 6A, G21 is an insertion loss graph, and G22 is a return loss graph. P21, P22, and P23 are resonance points with respect to about 3.5 GHz, 4 GHz, and 6.25 GHz in the return loss graph G12, and P30 is a resonance point in the insertion loss graph.

As described above, a single bandpass filter is adjustable to pass a single broadband frequency or two narrow band frequencies.

As set forth above, according to the embodiments in the present disclosure, using a bandpass filter for one broadband, a single-band bandpass filter may be varied to a dual-band bandpass filter according to a system to be applied, or a dual-band bandpass filter may be varied to a single-band bandpass filter on the contrary. Thus, one bandpass filter may be applied to respective systems having different passbands by region.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A sub-band adjustable bandpass filter, comprising:
a first resonance circuit configured to resonate at a first frequency;
a second resonance circuit configured to resonate at a second frequency different from the first frequency;
a first variable capacitance circuit connected between a first node connected to the first resonance circuit and a common node, the first variable capacitance circuit having a capacitance value being varied responsive to a first control signal;
a second variable capacitance circuit connected between a second node connected to the second resonance circuit and the common node, the second variable capacitance circuit having a capacitance value being varied responsive to a second control signal; and
an inductance circuit, the inductance circuit and the first variable capacitance circuit defining a first parallel resonance circuit, the inductance circuit and the second variable capacitance circuit defining a second parallel resonance circuit, the inductance circuit and the first variable capacitance circuit defining a first series resonance circuit, and the inductance circuit and the second variable capacitance circuit defining a second series resonance circuit.

2. The sub-band adjustable bandpass filter of claim 1, wherein resonance frequencies of the first parallel resonance circuit and the second parallel resonance circuit, and resonance frequencies of the first series resonance circuit and the second series resonance circuit are varied responsive to the first control signal and the second control signal, respectively.

3. The sub-band adjustable bandpass filter of claim 1, wherein the first resonance circuit comprises a first inductor and a first capacitor serially connected between a first terminal and the first node, and the first inductor and the first capacitor resonate in series at the first frequency.

4. The sub-band adjustable bandpass filter of claim 1, wherein the second resonance circuit comprises a second inductor and a second capacitor serially connected between a second terminal and the second node, and
the second inductor and the second capacitor resonate in series at the second frequency.

5. The sub-band adjustable bandpass filter of claim 1, wherein the first variable capacitance circuit comprises at least a first variable capacitor circuit connected between the first node and the common node, and
a capacitance value of the first variable capacitor circuit is varied responsive to the first control signal.

6. The sub-band adjustable bandpass filter of claim 1, wherein the second variable capacitance circuit comprises at least a second variable capacitor circuit connected between the second node and the common node, and
a capacitance value of the second variable capacitor circuit is varied responsive to the second control signal.

7. The sub-band adjustable bandpass filter of claim 1, wherein the inductance circuit comprises:
a first inductor, the first inductor and the first variable capacitance circuit defining the first parallel resonance circuit to resonate in parallel at a third frequency;
a second inductor, the second inductor and the second variable capacitance circuit defining the second parallel resonance circuit to resonate in parallel at a fourth frequency; and
a common inductor connected between the common node and a ground, the common inductor and the first variable capacitance circuit defining the first series resonance circuit, and the common inductor and the second variable capacitance circuit defining the second series resonance circuit, to resonate in series at a fifth frequency.

8. A sub-band adjustable bandpass filter, comprising:
a first resonance circuit configured to resonate at a first frequency;
a second resonance circuit configured to resonate at a second frequency different from the first frequency;
a first variable capacitance circuit connected between a first node connected to the first resonance circuit and a common node, the first variable capacitance circuit having a capacitance value being varied responsive to a first control signal;
a second variable capacitance circuit connected between a second node connected to the second resonance circuit and the common node, the second variable capacitance circuit having a capacitance value being varied responsive to a second control signal; and
an inductance circuit including a first inductor, a second inductor, and a common inductor connected between the common node and a ground,
the first inductor and the first variable capacitance circuit defining a first parallel resonance circuit, the second inductor and the second variable capacitance circuit defining a second parallel resonance circuit, the common inductor and the first variable capacitance circuit defining a first series resonance circuit, and the common inductor and the second variable capacitance circuit defining a second series resonance circuit,
wherein the first inductor and the second inductor form inductive coupling.

9. The sub-band adjustable bandpass filter in claim 8, wherein the first resonance circuit comprises the first inductor and a first capacitor serially connected between a first terminal and the first node in series, and
the first inductor and the first capacitor resonate in series at the first frequency.

10. The sub-band adjustable bandpass filter of claim 8, wherein the second resonance circuit comprises the second inductor and a second capacitor serially connected between a second terminal and the second node in series, and
the second inductor and the second capacitor resonate in series at the second frequency.

11. The sub-band adjustable bandpass filter of claim 8, wherein the first variable capacitance circuit comprises at least a first variable capacitor circuit connected between the first node and the common node, and
a capacitance value of the first variable capacitor circuit is varied responsive to the first control signal.

12. The sub-band adjustable bandpass filter of claim 8, wherein the second variable capacitance circuit comprises at least a second variable capacitor circuit connected between the second node and the common node, and
a capacitance value of the second variable capacitor circuit is varied responsive to the second control signal.

13. The sub-band adjustable bandpass filter of claim 8, wherein the first inductor of the inductance circuit and the first variable capacitance circuit configure the first parallel resonance circuit to resonate in parallel at a third frequency,
the second inductor of the inductance circuit and the second variable capacitance circuit configure the second parallel resonance circuit to resonate in parallel at a fourth frequency, and
the common inductor of the inductance circuit and the first variable capacitance circuit configure the first series resonance circuit and the common inductor thereof and the second variable capacitance circuit configure the second series resonance circuit, to resonate in series at a fifth frequency.

14. A bandpass filter, comprising:
resonance circuits coupled to variable capacitance circuits, respectively; and
an inductance circuit coupled to the variable capacitance variable circuits, the resonance circuits being individually controllable by respectively coupled variable capacitance circuit to resonate at different predetermined frequencies.

15. The bandpass filter of claim 14, wherein a first resonance circuit of the resonance circuits resonate at a first frequency between 2 GHz to 8 GHz.

16. The bandpass filter of claim 15, wherein a second resonance circuit of the resonance circuits resonate at a second frequency between 2 GHz to 8 GHz.

17. The bandpass filter of claim 16, wherein the first frequency is different from the second frequency.

18. The bandpass filter of claim 17, wherein each of the variable capacitance circuits comprises a control signal that is used to control the frequency of a respective resonance circuit.

19. The bandpass filter of claim 18, wherein the inductance circuit and the first variable capacitance circuit defines a first parallel resonance circuit, and the inductance circuit and the second variable capacitance circuit defines a second parallel resonance circuit.

20. An Ultra-wideband filter comprising the bandpass filter of claim 14.
